(19) United States
(12) Patent Application Publication
(10) Pub. No.: US 2025/0070042 A1
(43) Pub. Date: Feb. 27, 2025

(54) MODULE LEVEL COMPARTMENTAL INTEGRATED SHIELDING

(71) Applicant: Qorvo US, Inc., Greensboro, NC (US)

(72) Inventors: Thomas Scott Morris, Lewisville, NC (US); Mohsen Haji-Rahim, Chapel Hill, NC (US); Charles E. Carpenter, Orlando, FL (US); Brian Howard Calhoun, Oak Ridge, NC (US)

(21) Appl. No.: 18/802,670

(22) Filed: Aug. 13, 2024

Related U.S. Application Data
(60) Provisional application No. 63/534,680, filed on Aug. 25, 2023.

(51) Int. Cl. H01L 23/552; H01L 21/48; H01L 23/00; H01L 23/538; H01L 25/16

(52) U.S. Cl. CPC H01L 23/552; H01L 21/4825; H01L 21/4842; H01L 25/165; H01L 23/5383; H01L 24/16; H01L 2224/16238

(57) ABSTRACT

The disclosure relates to a shielded electronic module with compartmental integrated shielding. The disclosed shielded electronic module includes an electronic module having an interposer, a mold compound, a first device component, a second device component, and an interior shield wall, and a module shielding structure directly and completely covers a top surface and side surfaces of the electronic module. Herein, the first device component and the second device component are formed over a top surface of the interposer, and the mold compound resides over the top surface of the interposer and fully encapsulates the first device component and the second device component. The interior shield wall is a continuous metal sheet and extends vertically through the mold compound towards the top surface of the interposer to separate the first device component and the second device component. The module shielding structure is physically and electrically connected to the interior shield wall.

### RELATED APPLICATIONS

This application claims the benefit of provisional patent application Ser. No. 63/534,680, filed Aug. 25, 2023, the disclosure of which is hereby incorporated herein by reference in its entirety.

### FIELD OF THE DISCLOSURE

The disclosure relates to a shielded electronic module with compartmental integrated shielding and a fabrication process for making the same.

### BACKGROUND

Electronic components have become ubiquitous in modern society. The presence and strength of electromagnetic fields and signals have also become more prevalent. While many such devices depend on these signals to work, they can also include multiple components which can be damaged, interfered with, or rendered inoperable by electromagnetic fields emitted from alternative components or devices. Also of concern is the emission of unwanted electromagnetic fields which may be intercepted by, disrupted by, or interfered with the operation of alternative devices or equipment. This phenomenon is sometimes called electromagnetic interference (EMI) or crosstalk.

One way to reduce EMI is to shield electronic modules that cause EMI or that are sensitive to EMI. Typically, the shield comes in the form of a grounded enclosure covering the electronic module or a portion thereof. The grounded shield then blocks or absorbs incoming or outgoing electromagnetic emissions that could disrupt the electronic components within the enclosure, or any electromagnetic emission that may have unwanted effects if transmitted outwardly. When electromagnetic emissions from electronic components within the shield strike the interior surface of the shield, the electromagnetic emissions are electrically shorted through the grounded conductive material, thereby reducing emissions. Likewise, when emissions from outside the shield strike the exterior surface of the shield, a similar electrical short occurs, and the electronic components do not experience the emissions.

However, as the electronic modules continue to become smaller from miniaturization, creating effective shields that do not materially add to the size of the electronic module becomes more difficult. Further, it has been recognized that eddy radio frequency (RF) currents, which come from radiative components within a module, may exist within internal surfaces of the shield. When those eddy RF currents interact with other components, the performance of the overall device is negatively impacted.

As such, there is a need for an improved shielded electronic module design, which can reduce EMI from the external environment of the module and individually isolate radiative components within the module. In addition, there is also a need to manufacture the shielded electronic module in a cost-effective way without increasing the size and complexity of the final product.

### SUMMARY

The disclosure relates to a shielded electronic module with compartmental integrated shielding and a fabrication process for making the same. The disclosed shielded electronic module includes a module shielding structure and an electronic module having an interposer, a mold compound, at least one first device component, at least one second device component, and a first interior shield wall. Within the electronic module, the at least one first device component and the at least one second device component are formed over a top surface of the interposer, and the mold compound resides over the top surface of the interposer and fully encapsulates the at least one first device component and the at least one second device component. The first interior shield wall is a continuous metal sheet and extends vertically through the mold compound towards the top surface of the interposer to separate the at least one first device component and the at least one second device component. Herein, a top surface of the electronic module includes a top surface of the mold compound and a top surface of the first interior shield wall. The module shielding structure directly and completely covers the top surface and side surfaces of the electronic module, such that the module shielding structure and the first interior shield wall are physically and electrically connected.

In one embodiment of the disclosed shielded electronic module, the electronic module further includes at least one third device component and a second interior shield wall. Herein, the at least one third device component is formed over the top surface of the interposer, and the mold compound fully encapsulates the third device component. The second interior shield wall is a continuous metal sheet and extends vertically through the mold compound towards the top surface of the interposer to separate the at least one first device component from the at least one third device component. Herein, the top surface of the electronic module further includes a top surface of the second interior shield wall. The module shielding structure and the second interior shield wall are physically and electrically connected.

In one embodiment of the disclosed shielded electronic module, the first interior shield wall and the second interior shield wall are separated from each other.

In one embodiment of the disclosed shielded electronic module, the first interior shield wall and the second interior shield wall are physically connected to each other.

In one embodiment of the disclosed shielded electronic module, the electronic module further includes at least one third device component, which is formed over the top surface of the interposer. Herein, the mold compound fully encapsulates the at least one third device component, and the first interior shield wall separates the at least one third device component from the at least one first device component.

In one embodiment of the disclosed shielded electronic module, no interior shield wall is between the at least one second device component and the at least one third device component.

In one embodiment of the disclosed shielded electronic module, the first interior shield wall includes a number of holes.

In one embodiment of the disclosed shielded electronic module, the first interior shield wall is in the shape of a rectangle, a square, a trapezoid, or a combination thereof.

In one embodiment of the disclosed shielded electronic module, the first interior shield wall is a copper sheet.

In one embodiment of the disclosed shielded electronic module, the first interior shield wall has a width of at least 100 μm, and a thickness of at least 25 μm.

In one embodiment of the disclosed shielded electronic module, each of the at least one first device component and the at least one second device component is one of a flip-chip die, a wire-bonding die, a surface mounted device (SMD), an inductor, a capacitor, and a resistor.

In one embodiment of the disclosed shielded electronic module, the at least one first device component includes a number of first device components, and the at least one second device component includes a number of second device components. Herein, the first interior shield wall separates the first device components from the second device components.

According to an exemplary process, a first assembly including an interposer, a first device component, a second device component, and a sacrificial shielding structure, is first provided. Herein, the first device component and the second device component are formed over a top surface of the interposer. The sacrificial shielding structure, which at least includes a sacrificial joining member, a first interior shield wall, and a second interior shield wall, is formed over the top surface of the interposer. The sacrificial joining member is configured to keep the first interior shield wall and the second interior shield wall tied together. The first device component is covered by the sacrificial shielding structure, while the second device component is outside the sacrificial shielding structure, such that the first device component and the second device component are separated by the first interior shield wall. The first interior shield wall and the second interior shield wall are taller than the first device component and the second device component. Next, a mold compound is applied over the top surface of the interposer to fully encapsulate the first device component, the second device component, and the sacrificial shielding structure. The mold compound is then thinned down to provide an electronic module. Specifically, the mold compound is thinned down until the sacrificial joining member is removed and the first interior shield wall and the second interior shield wall are exposed through the mold compound. As such, a top surface of the electronic module includes a top surface of the mold compound and exposed top surfaces of the first interior shield wall and the second interior shield wall. Lastly, a mold shielding structure is applied to cover the top surface and side surfaces of the electronic module directly and completely. The module shielding structure is physically and electrically connected to the first interior shield wall and the second interior shield wall.

In one embodiment of the exemplary process, the sacrificial shielding structure is formed by firstly providing a metal sheet. Next, portions of the metal sheet are etched to provide an etched metal sheet. Herein, the etched metal sheet includes at least a joining portion, a first wall portion, and a second wall portion. The joining portion is connected to both the first wall portion and the second wall portion. Each of the first wall portion and the second wall portion is bent down to provide the sacrificial shielding structure, where the first bent-down wall portion forms the first interior shield wall of the sacrificial shielding structure, the second bent-down wall portion forms the second interior shield wall of the sacrificial shielding structure, and the unbent joining portion forms the sacrificial joining member of the sacrificial shielding structure.

In one embodiment of the exemplary process, the sacrificial shielding structure is formed by firstly providing a metal sheet, the first interior shield wall, and the second interior shield wall. Next, the first interior shield wall and the second interior shield wall are welded on a bottom surface of the metal sheet to provide the sacrificial shielding structure.

In one embodiment of the exemplary process, the interposer includes connection pads and connection tracks on the top surface of the interposer. Herein, the first assembly is provided by firstly placing the first device component and the second device component over the top surface of the interposer, such that the first device component and the second device component are connected to corresponding connection pads, respectively. Next, the sacrificial shielding structure is placed over the top surface of the interposer, where the first interior shield wall and the second interior shield wall are connected to corresponding connection tracks, respectively. The first device component, the second device component, the first interior shield wall, and the second interior shield wall are soldered to the interposer simultaneously.

In one embodiment of the exemplary process, each of the first interior shield wall and the second interior shield wall is a copper sheet.

In one embodiment of the exemplary process, each of the first interior shield wall and the second interior shield wall includes a plurality of holes.

In one embodiment of the exemplary process, each of the first interior shield wall and the second interior shield wall has a width of at least 100 μm, and a thickness of at least 25 μm.

In one embodiment of the exemplary process, each of the first device component and the second device component is one of a flip-chip die, a wire-bonding die, a surface mounted device (SMD), an inductor, a capacitor, or a resistor.

According to one embodiment, a communication device includes a control system, a baseband processor, receive circuitry, and transmit circuitry. Herein, at least one or any combination of the control system, the baseband processer, the transmit circuitry, and the receive circuitry is implemented in a shielded electronic module, which includes an electronic module with an interposer, a mold compound, at least one first device component, at least one second device component, and a first interior shield wall, and a module shielding structure directly and completely covering a top surface and side surfaces of the electronic module. Herein, the at least one first device component and the at least one second device component are formed over a top surface of the interposer. The mold compound resides over the top surface of the interposer and fully encapsulates the at least one first device component and the at least one second device component. The first interior shield wall is a continuous metal sheet and extends vertically through the mold compound towards the top surface of the interposer to separate the at least one first device component and the at least one second device component. The top surface of the electronic module includes a top surface of the mold compound and a top surface of the first interior shield wall. The module shielding structure is physically and electrically connected to the first interior shield wall.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A and 1B illustrate an exemplary shielded electronic module according to some embodiments of the present disclosure.

FIG. 2 is a flow diagram that illustrates an exemplary process to provide the shielded electronic module illustrated in FIG. 1A according to some embodiments of the present disclosure.

FIGS. 3A-9 illustrate the steps associated with the process shown in FIG. 2.

FIG. 10 illustrates a block diagram of a communication device, which may include the shielded electronic module illustrated in FIGS. 1A-1B according to some embodiments of the present disclosure.

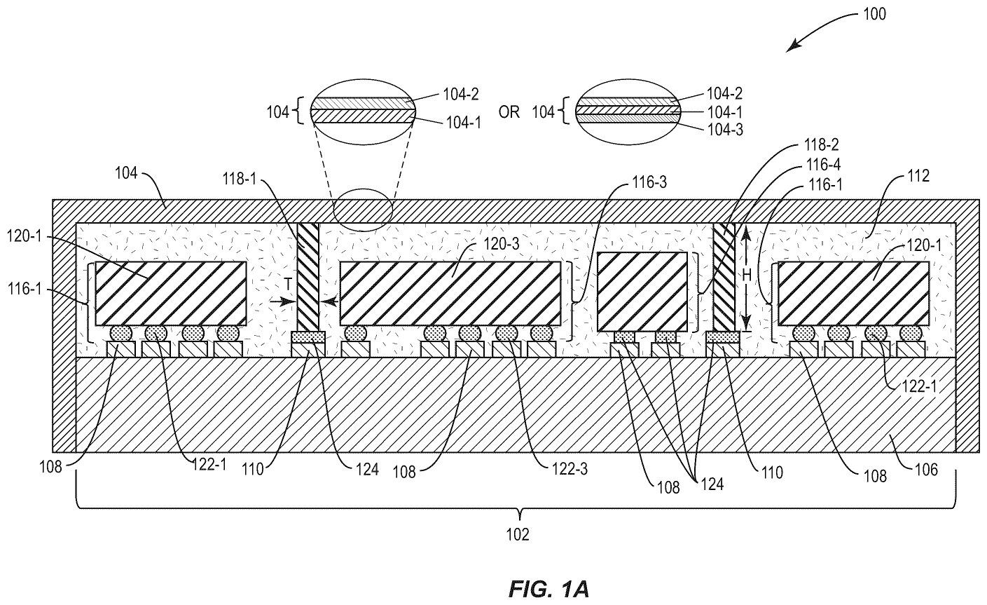

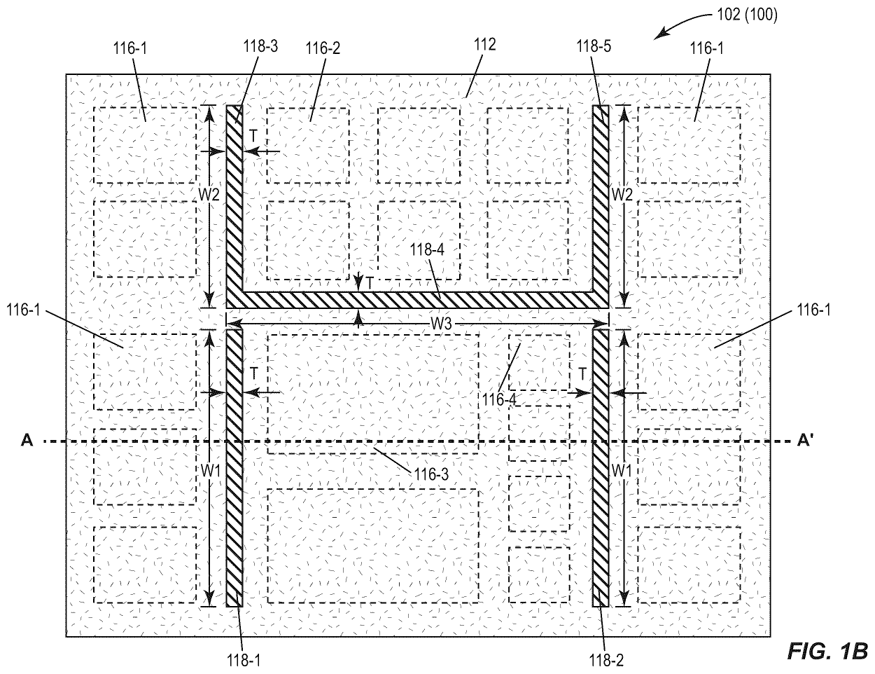

It will be understood that for clear illustrations, FIGS. 1A-10 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The disclosure relates to a shielded electronic module with compartmental integrated shielding, which is capable of reducing electromagnetic interference (EMI) from an external environment of the module and is capable of individually isolating radiative components within the module, and a fabrication process for making the same. FIGS. 1A-1B illustrate an exemplary shielded electronic module 100 composed of an electronic module 102 with a module shielding structure 104 according to some embodiments of the present disclosure. FIG. 1A is a cross-sectional view of the shielded electronic module 100, and FIG. 1B is a top view of the electronic module 102 (without the module shielding structure 104 for clarity). The cross-sectional view of the shielded electronic module 100 shown in FIG. 1A is a portion of the shielded electronic module 100 along a dotted line A-A′.

Herein, the electronic module 102 includes an interposer 106 with connection pads 108 and connection tracks 110 (for clarity, only certain connection pads are labeled with reference numbers), a mold compound 112, a number of device components 116, and interior shield walls 118. For the purpose of this illustration, the device components 116 include ten first flip-chip dies 116-1, six second flip-chip dies 116-2, two third flip-chip dies 116-3, and four surface mounted devices (SMDs) 116-4 (for clarity, only certain first flip-chip dies, certain second flip-chip dies, certain third flip-chip dies, and certain SMDs are labeled with reference numbers). The interior shield walls 118 include a first interior shield wall 118-1, a second interior shield wall 118-2, a third interior shield wall 118-3, a fourth interior shield wall 118-4, and a fifth interior shield wall 118-5. The first interior shield wall 118-1 separates the third flip-chip dies 116-3 from the first flip-chip dies 116-1, the second interior shield wall 118-2 separates the SMDs 116-4 from the first flip-chip dies 116-1, the third interior shield wall 118-3 separates the second flip-chip dies 116-2 from the first flip-chip dies 116-1, the fourth interior shield wall 118-4 separates the second flip-chip dies 116-2 from the third flip-chip dies 116-3 and the SMDs 116-4, and the fifth interior shield wall 118-5 separates the second flip-chip dies 116-2 from the first flip-chip dies 116-1. In different applications, the electronic module 102 may include fewer or more device components 116 and include fewer or more interior shield walls 118. The device components 116 may include other active/passive component types, like wire-bonding dies, inductors, capacitors, resistors, and etc. The interior shield walls 118 may have different sizes (i.e., different widths, each interior shield wall 118 always has a same height) and orientations. In addition, the device components 116 and the interior shield walls 118 may be configured in different layouts within the electronic module 102.

In detail, each device component 116 is attached to corresponding connection pads 108 on a top surface of the interposer 106. In this embodiment, each first flip-chip die 116-1 includes a first die body 120-1 and multiple first solder bumps 122-1 at a bottom surface of the first die body 120-1. Each first solder bump 122-1 is electrically and physically connected to a corresponding connection pad 108. Each third flip-chip die 116-3 includes a third die body 120-3 and multiple third solder bumps 122-3 at a bottom surface of the third die body 120-3. Each third solder bump 122-3 is electrically and physically connected to a corresponding connection pad 108. Each SMD 116-4 is attached to the corresponding connection pads 108 via a solder paste 124 (details of the second flip-chip dies 116-2 are similar to the first flip-chip dies 116-1, and not shown for simplicity).

The mold compound 112, which may be an organic epoxy resin system, resides over the top surface of the interposer 106. The mold compound 112 fully encapsulates each device component 116, and fills gaps between the bottom surface of each device component 116 and the top surface of the interposer 106. In some temperature sensitive applications, the mold compound 112 may have a thermal conductivity greater than 1 W/m·K and may be formed of thermoplastics or thermoset polymer materials, such as polyphenylene sulfide (PPS), epoxy doped with boron nitride, aluminum nitride, alumina, carbon nanotubes, or diamond-like thermal additives, or the like.

Each interior shield wall 118 extends vertically through the mold compound 112, and is attached to a corresponding connection track 110 on the top surface of the interposer 106 via the solder paste 124. Each interior shield wall 118 may be formed of a metal material, such as copper, aluminum, molybdenum copper, stainless steel, alloys, or any other conductive materials, and has a thickness T between 25 μm and 100 μm. Each interior shield wall 118 is a continuous metal sheet having a same height H between 50 μm and 1000 μm, which is typically greater than a height of any device component 116. In different applications, the interior shield walls 118 may have different widths W of at least 100 μm (e.g., the first interior shield wall 118-1 and the second interior shield wall 118-2 have a first width W1, the third interior shield wall 118-3 and the fifth interior shield wall 118-5 have a second width W2, and the fourth interior shield wall 118-4 has a third width W3).

In this embodiment, a top surface of the electronic module 102 is a top surface of the mold compound 112 with top surfaces of the interior shield walls 118, a bottom surface of the electronic module 102 is a bottom surface of the interposer 106, and a side surface of the electronic module 102 is a combination of a side surface of the mold compound 112 and a side surface of the interposer 106. The module shielding structure 104 directly and completely covers the top surface of the electronic module 102 and completely covers the side surface of the electronic module 102, while the bottom surface of the electronic module 102 is exposed. Herein and hereafter, completely covering a surface refers to covering at least 99% of such surface. As such, each interior shield wall 118 is in contact with the module shielding structure 104.

The module shielding structure 104 includes at least a first module shielding layer 104-1 and a second module shielding layer 104-2. The first module shielding layer 104-1 completely covers the top surface and the side surface of the electronic module 102, and may be formed of copper, aluminum, silver, gold, or other conductive materials with a thickness between 3 μm and 16 μm. The second module shielding layer 104-2 resides over the first module shielding layer 104-1 and may be formed of stainless steel or nickel with a thickness between 0.3 μm and 3 μm. In order to achieve a superior adhesion, the module shielding structure 104 may further include a third module shielding layer 104-3 (as a seed layer) that is formed of stainless steel, copper, aluminum, silver, gold, or other conductive materials with a thickness between 0.1 μm and 1.5 μm. The third module shielding layer 104-3 may directly and completely cover the top surface and the side surface of the electronic module 102, and the first module shielding layer 104-1 resides over the third module shielding layer 104-3. For a non-limiting example, the third module shielding layer 104-3 (as the seed layer) is formed of stainless steel with a 0.1 μm thickness, the first module shielding layer 104-1 is formed of copper with a 4 μm thickness, and the second module shielding layer 104-2 is formed of stainless steel with a 0.3 μm thickness.

The interposer 106 is a multilayer laminate with dielectric layers and redistribution routines inside the dielectric layers (not shown, e.g., a printed circuit board). The connection pads 108 and the connection tracks 110 at the top surface of the interposer 106 are formed of a metal material. The interposer 106 is configured to provide electrical connections between the electronic components 116 within the electronic module 102 (e.g., between the first flip-chip dies 116-1 and the third flip-chip dies 116-3, and between the third flip-chip dies 116-3 and the SMDs 116-4) and electrical connections between the electronic components 116 of the electronic module 102 and external electronic components (not shown for simplicity). The interposer 106 also provides mechanical support to the device components 116.

In addition, the interposer 106 may include a ground plane (not shown) electrically connected to the module shielding structure 104. Since the interior shield walls 118 are conductive and each interior shield wall 118 is in contact with the module shielding structure 104, once the module shielding structure 104 is grounded, each interior shield wall 118 is also grounded. As a result, the interior shield walls 118, which extend vertically from the top surface of the interposer 106 to the module shielding structure 104, are capable of preventing electromagnetic radiation within the electronic module 102. In this embodiment, the interior shield walls 118 are configured to provide electromagnetic shielding between the first flip-chip dies 116-1 and the second flip-chip dies 116-2, between the first flip-chip dies 116-1 and the third flip-chip dies 116-3, between the first flip-chip dies 116-1 and the fourth flip-chip dies 116-4, between the second flip-chip dies 116-2 and the third flip-chip dies 116-3, between the second flip-chip dies 116-2 and the SMDs 116-4, and between the first flip-chip dies 116-1 and the SMDs 116-4 (e.g., the interior shield wall 118 is capable of preventing the electromagnetic radiation of the SMDs 116-4 from interfering with the first flip-chip dies 116-1).

With different layouts of the device components 116 and the interior shield walls 118, the interior shield walls 118 will provide different electromagnetic shielding among device components 116. In a non-limiting example, the second flip-chip dies 116-2 may be radiative components or electronic components that are superiorly sensitive to external interference (e.g., Bulk Acoustic Wave (BAW) resonators/filters or Surface Acoustic Wave (SAW) resonators/filters). Since the second flip-chip dies 116-2 are shielded by the combination of the module shielding structure 104 and the interior shield walls 118, the electromagnetic field generated by other device components 116 (e.g., the first flip-chip dies 116-1, like power amplifiers) will not affect the second flip-chip dies 116-2.

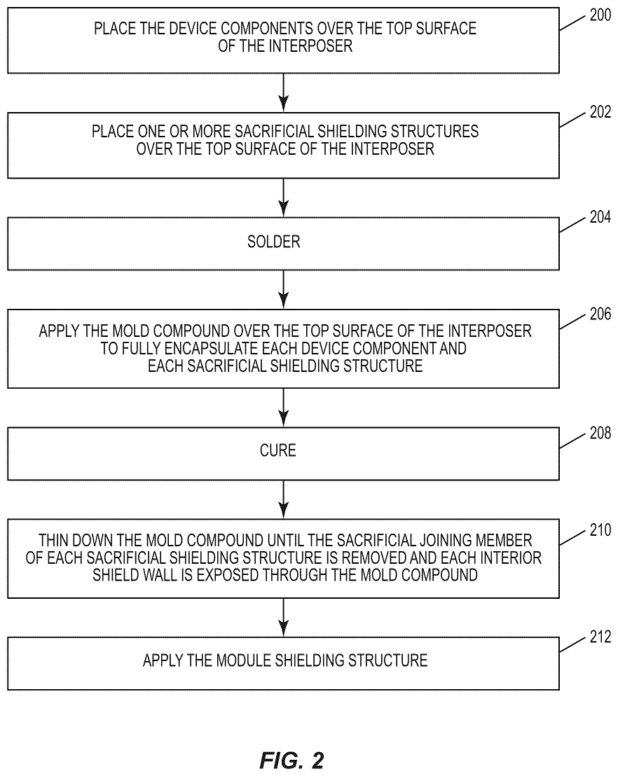

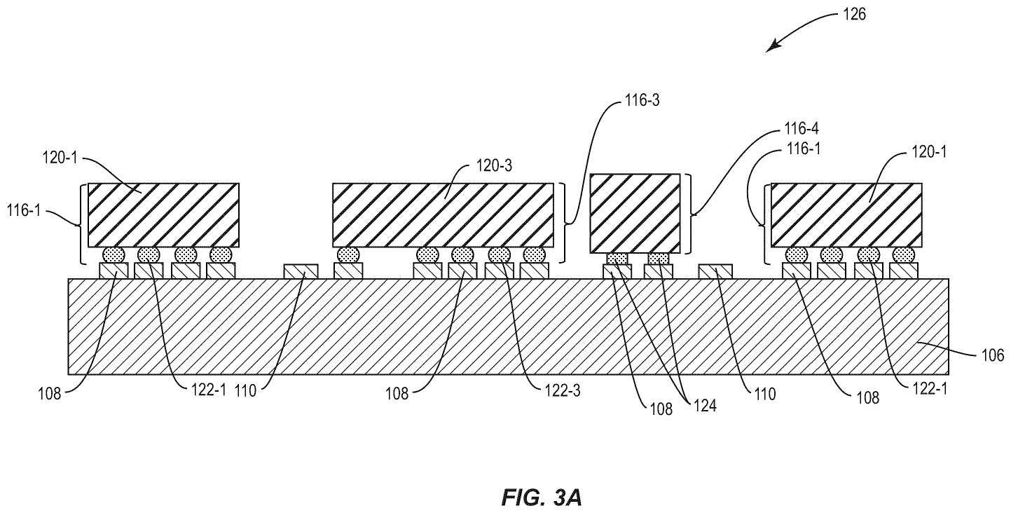

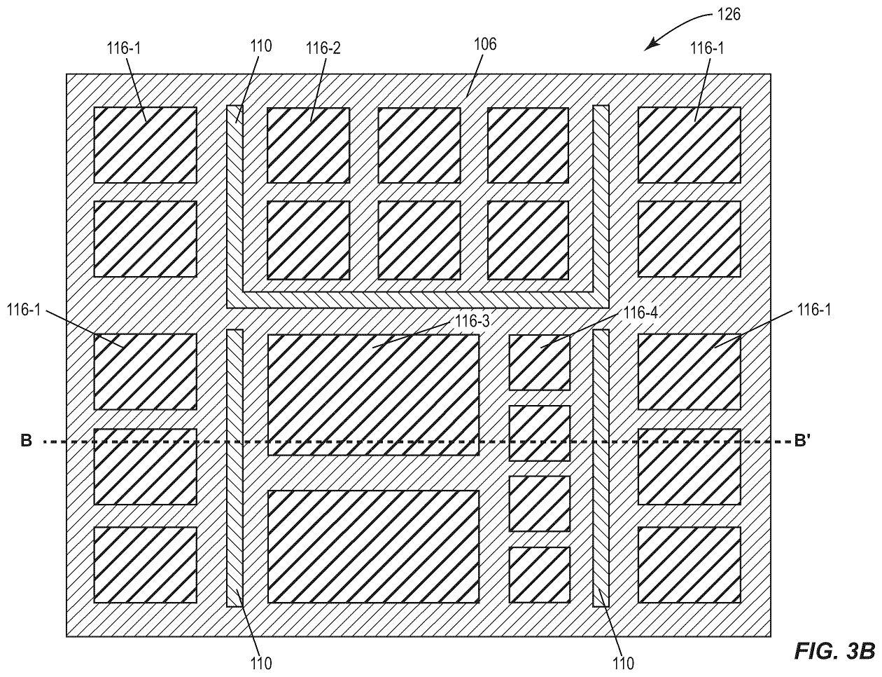

FIG. 2 provides a flow diagram that illustrates an exemplary fabrication process to implement the shielded electronic module 100 shown in FIG. 1A. FIGS. 3-9 illustrate the steps associated with the fabrication process provided in FIG. 2. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 3-9.

Initially, the device components 116 are placed over the top surface of the interposer 106 to provide a first assembly 126 as illustrated in FIGS. 3A and 3B (step 200). FIG. 3A is a cross-sectional view of the first assembly 126, and FIG. 3B shows a top view of the first assembly 126. The cross-sectional view shown in FIG. 3A is a portion of the first assembly 126 along a dotted line B-B′. For the purpose of this illustration, the device components 116 include ten first flip-chip dies 116-1, six second flip-chip dies 116-2, two third flip-chip dies 116-3, and four SMDs 116-4 (for clarity, only certain first flip-chip dies, certain second flip-chip dies, certain third flip-chip dies, and certain SMDs are labeled with reference numbers). In different applications, there might be fewer or more device components 116 placed over the interposer 106, and the device components 116 may include other active/passive component types, like wire-bonding dies, inductors, capacitors, resistors, etc.

Herein, each device component 116 is in contact with the corresponding connection pads 108, and does not reside on any connection track 110. The connection tracks 110 are configured to engage the interior shield walls 118 with the interposer 106 in the following steps and are located based on internal shielding requirements. In detail, each first flip-chip die 116-1 includes the first die body 120-1 and the first solder bumps 122-1, which are physically in contact with the corresponding connection pads 108, respectively. The third flip-chip die 116-3 includes the third die body 120-3 and the third solder bumps 122-3, which are physically in contact with the corresponding connection pads 108, respectively. The SMD 116-4 is placed over the corresponding connection pads 108 via the solder paste 124. The second flip-chip dies 116-2 are also physically in contact with corresponding connection pads 108 via solder balls (similar to the first flip-chip dies 116-1, not shown for simplicity).

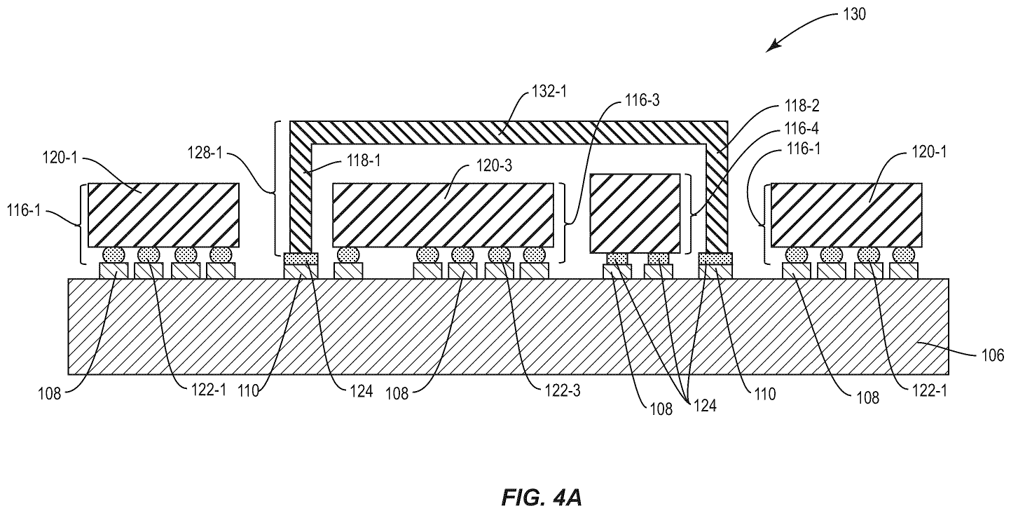

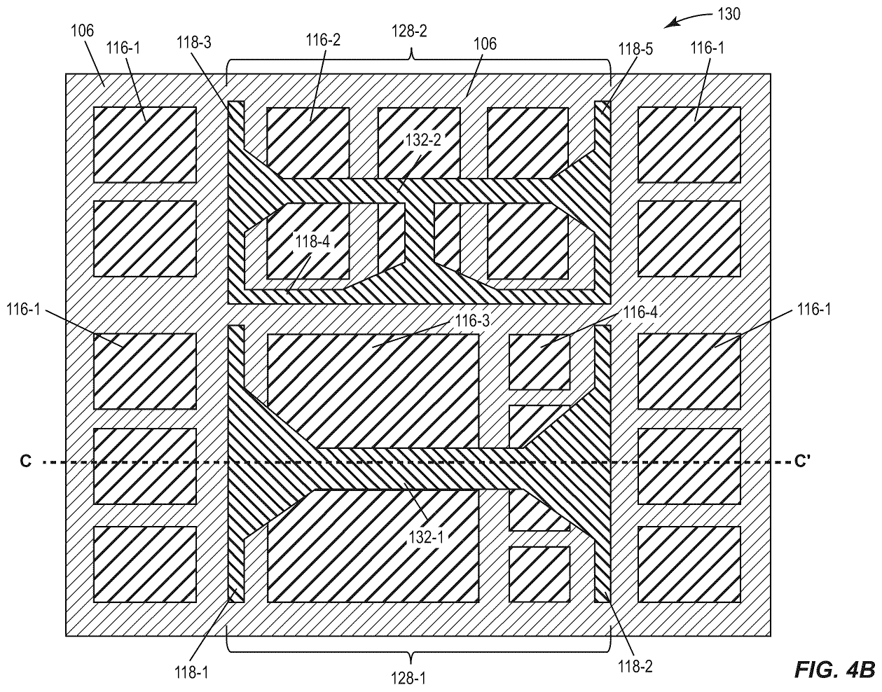

Next, one or more sacrificial shielding structures 128 are placed over the top surface of the interposer 106 to provide a second assembly 130 (step 202) as illustrated in FIGS. 4A and 4B. FIG. 4A is a cross-sectional view of the assembly 130, and FIG. 4B shows a top view of the assembly 130. The cross-sectional view shown in FIG. 4A is a portion of the assembly 130 along a dotted line C-C′. For the purpose of this illustration, there are two sacrificial shielding structures 128 (e.g., a first sacrificial shielding structure 128-1 and a second sacrificial shielding structure 128-2) provided to cover certain device components 116. The first sacrificial shielding structure 128-1 includes the first interior shield wall 118-1, the second interior shield wall 118-2, and a first sacrificial joining member 132-1, which is configured to connect the first interior shield wall 118-1 and the second interior shield wall 118-2, and to provide structural stability to the first interior shield wall 118-1 and the second interior shield wall 118-2. The second sacrificial shielding structure 128-2 includes the third interior shield wall 118-3, the fourth interior shield wall 118-4, the fifth interior shield wall 118-5, and a second sacrificial joining member 132-2, which is configured to connect the third interior shield wall 118-3, the fourth interior shield wall 118-4, and the fifth interior shield wall 118-5, and to provide structural stability to the third interior shield wall 118-3, the fourth interior shield wall 118-4, and the fifth interior shield wall 118-5. The first sacrificial shielding structure 128-1 is configured to cover the third flip-chip dies 116-3 and the SMDs 116-4, and to separate the third flip-chip dies 116-3 and the SMDs 116-4 from the first flip-chip dies 116-1 by the first and second interior shield walls 118-1 and 118-2. The second sacrificial shielding structure 128-2 is configured to cover the second flip-chip dies 116-2, and to separate the second flip-chip dies 116-2 from the first flip-chip dies 116-1, the third flip-chip dies 116-3, and the SMDs 116-4 by the third, fourth, and fifth interior shield walls 118-3, 118-4, and 118-5. In different applications, there might be fewer or more sacrificial shielding structures 128 placed over the interposer 106. Each sacrificial shielding structure 128 may include two or more interior shield walls 118 and one sacrificial joining member 132 that connects these interior shield walls 118 for structural stability. Notice that the shape of the sacrificial joining members 132 for different sacrificial shielding structures 128 might be different. Each sacrificial joining member 132 should be minimal in size, just enough to keep corresponding interior shield walls 118 tied together for structural stability.

Herein, the interior shield walls 118 of each sacrificial shielding structure 128 are in contact with corresponding connection tracks 110, respectively, via the solder paste 124. Each sacrificial shielding structure 128 may be formed of a metal material, such as copper, aluminum, molybdenum copper, stainless steel, alloys, or any other conductive materials. A soldering step is then followed (step 204, not illustrated). The solder bumps 122/solder paste 124 of each device component 116 and the solder paste 124 underneath each interior shield wall 118 are soldered at the same time. As such, each device component 116 and each interior shield wall 118 are physically and electrically connected to the interposer 106 (via the solder bumps 122/solder paste 124). This single soldering step will help to reduce the overall cost and time of the fabrication process, and improve reliability of the final product. In some applications, the solder paste 124 used underneath the SMDs 116-4 and/or the interior shield walls 118 may be replaced by a metal filled epoxy, or another conductive material.

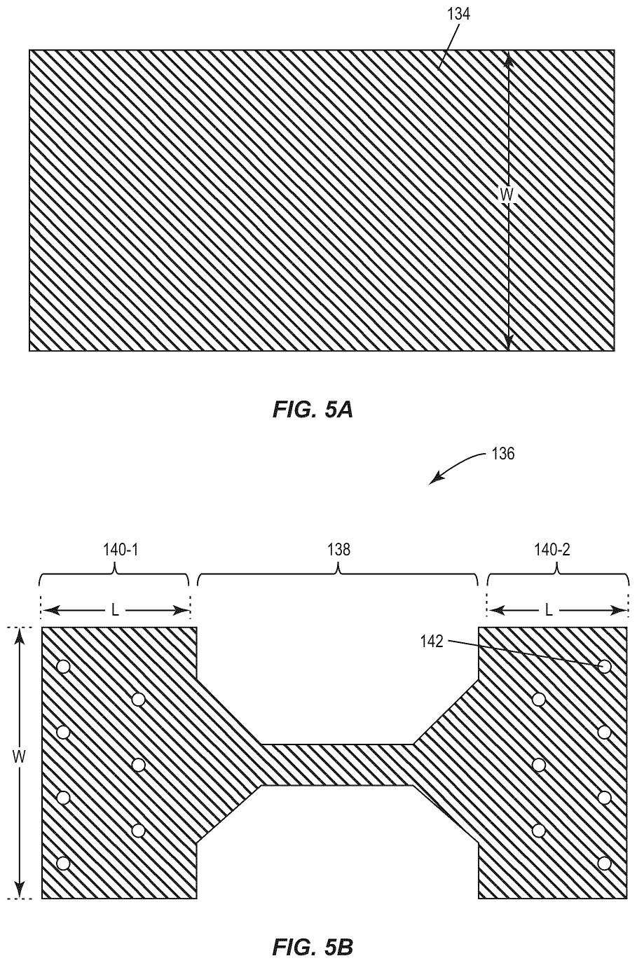

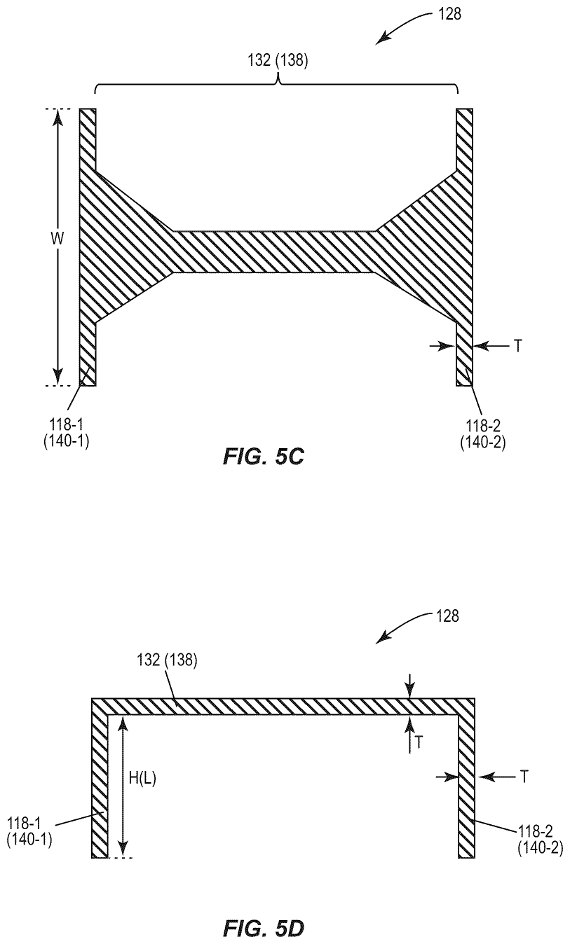

FIGS. 5A-5D illustrate an exemplary process of forming one sacrificial shielding structure 128 (e.g., the first sacrificial shielding structure 128-1). First, a metal sheet 134 is provided as illustrated in FIG. 5A. The metal sheet 134 may be formed of copper, aluminum, molybdenum copper, stainless steel, alloys, or any other conductive materials. The metal sheet 134 has a width of at least 100 μm, and a thickness T (not shown) between 25 μm and 100 μm.

Next, unneeded portions of the metal sheet 134 are etched to provide an etched metal sheet 136, as illustrated in FIG. 5B. The etched metal sheet 136 includes a joining portion 138 and wall portions 140. Typically, the unneeded portions are etched to form the joining portion 138, which is connected to the wall portions 140. Each wall portion 140 is a continuous portion, shaped as a rectangle, a square, a trapezoid, or a combination of these shapes. For the purpose of this illustration, the etched metal sheet 136 includes two wall portions 140 with a rectangular shape (a first wall portion 140-1 and a second wall portion 140-2), and the joining portion 138 has a dumbbell shape. In different applications, there might be more wall portions connected to the joining portion 138, and/or the wall portions 140 and the joining portion 138 may have different shapes. Herein, each wall portion 140 may have a same length L between 50 μm and 1000 μm. In some embodiments, each wall portion 140 may include multiple etched holes 142, which help with outgassing in the soldering step and/or in a following molding step (details are described below). The etched holes 142 may also be formed in this etching step at the same time as the joining portion 138. Each etched hole 142 may be in the shape of a circle, a square, or other geometrical shape, with a diameter between 25 μm and 200 μm.

Each wall portion 140 is bent down to form the sacrificial shielding structure 128 as illustrated in FIGS. 5C and 5D. FIG. 5C shows a top view of the sacrificial shielding structure 128, and FIG. 5D shows a cross-sectional view of the sacrificial shielding structure 128. Herein, the first bent-down wall portion 140-1 forms the first interior shield wall 118-1 of the sacrificial shielding structure 128, the second bent-down wall portion 140-2 forms the second interior shield wall 118-2 of the sacrificial shielding structure 128, and the unbent joining portion 138 forms the sacrificial joining member 132 of the sacrificial shielding structure 128. The sacrificial joining member 132 and each interior shield wall 118 have the thickness T between 25 μm and 100 μm. Since the interior shield walls 118 have a same height H (i.e., the wall portions 140 have a same length L) and the sacrificial joining member 132 keeps the interior shield walls 118 tied together, the sacrificial shielding structure 128 is stable enough to be placed on the interposer 106.

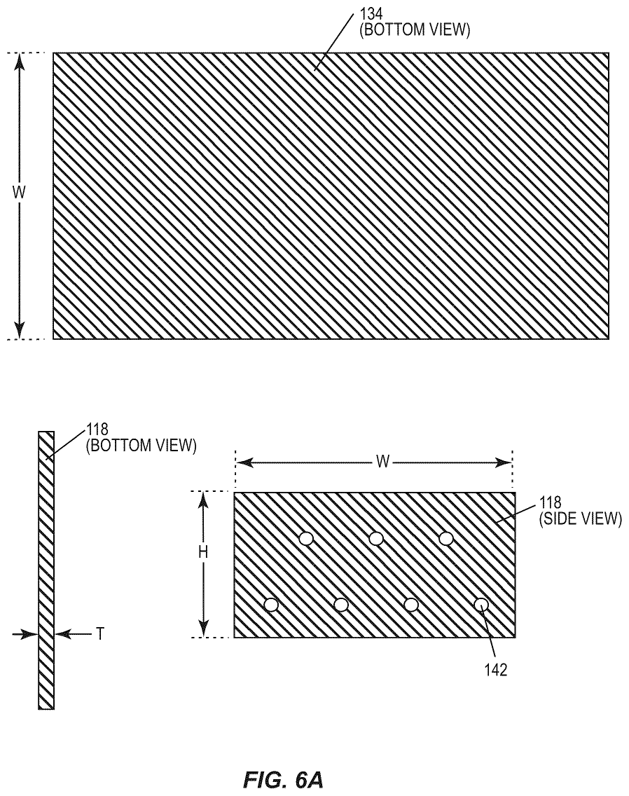

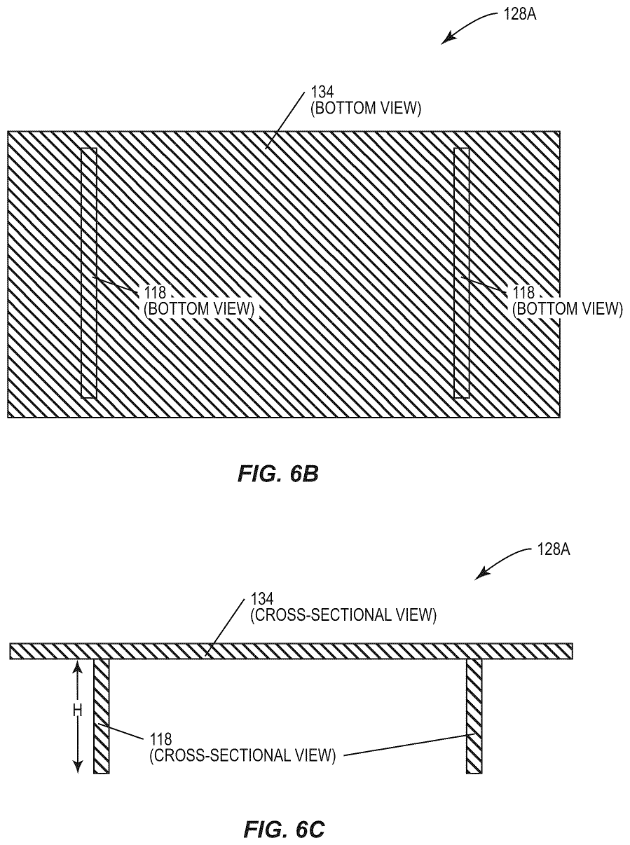

FIGS. 6A-6C illustrate an alternative process of forming one sacrificial shielding structure. First, the metal sheet 134 and the interior shield walls 118 are provided as illustrated in FIG. 6A. Both the metal sheet 134 and the interior shield walls 118 may be formed of a metal material, such as copper, aluminum, molybdenum copper, stainless steel, alloys, or any other conductive materials. Each interior shield wall 118 may have a thickness T between 25 μm and 100 μm, and a width W of least 100 μm. Herein, each interior shield wall 118 has a same height H between 50 μm and 1000 μm. In some embodiments, each interior shield wall 118 may include the etched holes 142, which help with outgassing in the soldering step and/or in the following molding step (details are described below).

Next, the interior shield walls 118 are placed and ultrasonic or arc welded on a bottom surface of the metal sheet 134 to provide an alternative sacrificial shielding structure 128A, as illustrated in FIGS. 6B and 6C. FIG. 6B shows a bottom view of the alternative sacrificial shielding structure 128A, and FIG. 6C shows a cross-sectional view of the alternative sacrificial shielding structure 128A. For the purpose of this illustration, there are only two interior shield walls 118 welded on the bottom surface of the metal sheet 134 (e.g., one at the left side and one at the right side). In different applications, there might be three or more interior shield walls 118 welded on the bottom surface of the metal sheet 134 with a different layout configuration.

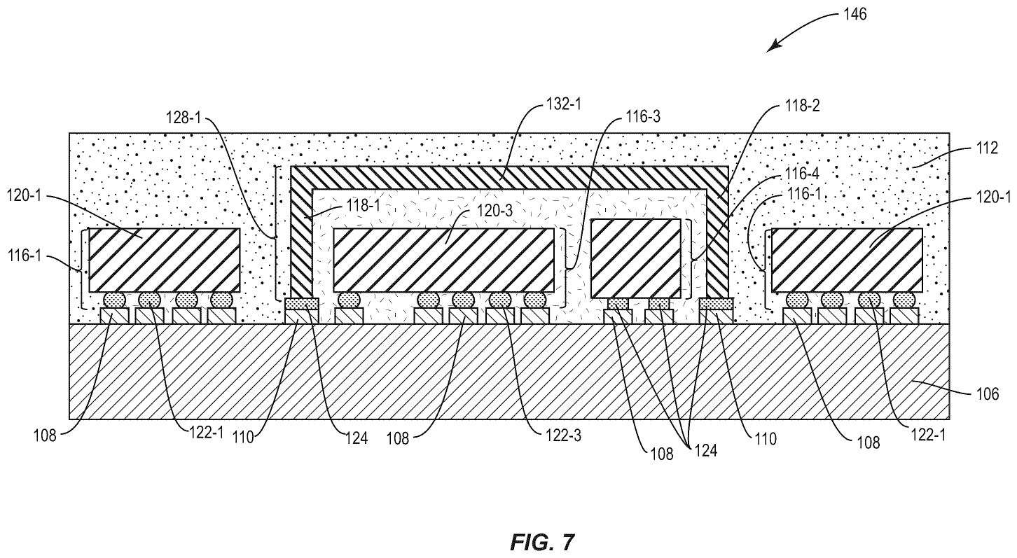

After each sacrificial shielding structure 128 and each device component 116 are soldered to the interposer 106 (i.e., after the soldering step), the mold compound 112 is applied over the top surface of the interposer 106 to provide a molded module 146, as illustrated in FIG. 7 (step 206). The mold compound 112 fully encapsulates each device component 116 and each sacrificial shielding structure 128, and fills gaps between a bottom surface of each device component 116 and the top surface of the interposer 106 (i.e., fills gaps around the solder bumps 122 and around the connection pads 108). The mold compound 112 may be applied by various procedures, such as sheet molding, overmolding, compression molding, transfer molding, dam fill encapsulation, or screen print encapsulation. As described above, each interior shield wall 118 may include the etched holes 142 (see FIGS. 5B/6A). When the mold compound 112 is applied to encapsulate the device components 116 covered by one sacrificial shielding structure 128 (e.g., the third flip-chip dies 116-3 and the SMDs 116-4 covered by the first sacrificial shielding structure 128-1), the etched holes 142 on the interior shield walls 118 will help with outgassing. As such, the mold compound 112 may better seal the device components 116 without voids.

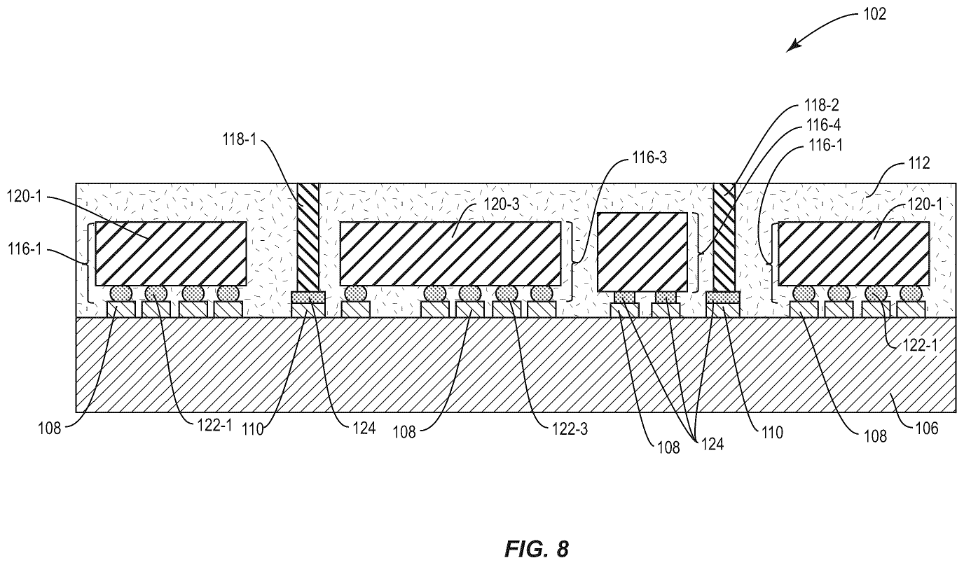

A curing step (step 208) is followed to harden the mold compound 112. The curing temperature is between 100° C. and 320° C. depending on which material is used as the mold compound 112. The mold compound 112 is then thinned down to provide the electronic modules 102, as illustrated in FIG. 8 (step 210). The mold compound 112 is thinned down until the sacrificial joining member 132 of each sacrificial shielding structure 128 (e.g., the first sacrificial joining member 132-1 of the first sacrificial shielding structure 128-1) is removed and the interior shield walls 118 of each sacrificial shielding structure 128 (e.g., the first interior shield wall 118-1 and the second interior shield wall 118-2 of the first sacrificial shielding structure 128-1) are exposed through the mold compound 112 (i.e., the top surface of each interior shield wall 118 is not covered by the mold compound 112). The thinning procedure may be done with a mechanical grinding process. Herein, since each device component 116 is lower than the interior shield walls 118, each device component 116 is not exposed and remains fully encapsulated by the mold compound 112.

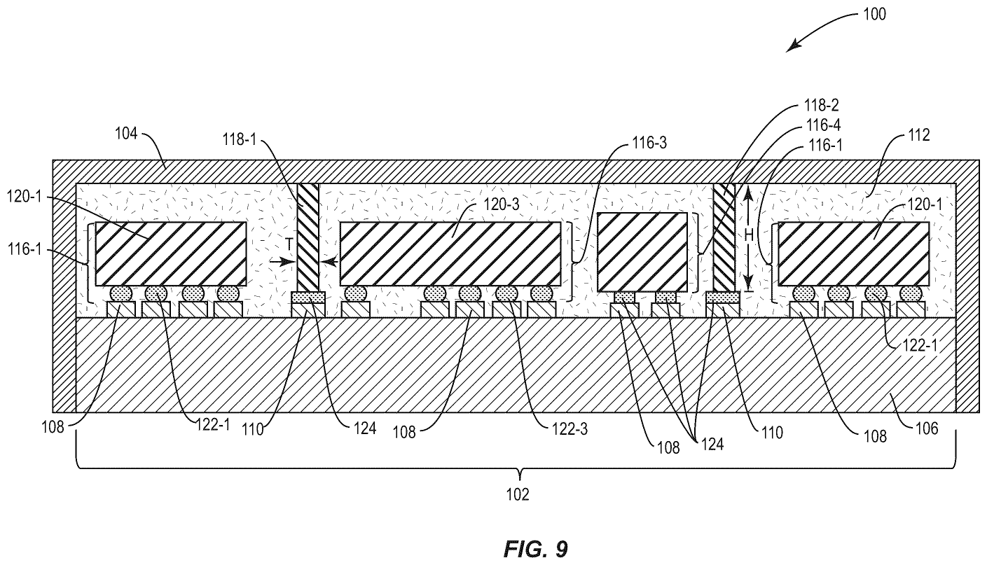

Lastly, the module shielding structure 104 is applied to the electronic module 102 to form the shielded electronic module 100, as illustrated in FIG. 9 (step 212). The module shielding structure 104 directly and completely covers the top surface and the side surface of the electronic module 102, while the bottom surface of the electronic module 102 is exposed. Since the top surface of the electronic module 102 is the top surface of the mold compound 112 with the exposed top surfaces of the interior shield walls 118, the module shielding structure 104 is physically and electrically connected to each interior shield wall 118. Herein, the module shielding structure 104 reduces EMI from an external environment of the shielded electronic module 100, while the interior shield walls 118 prevent electromagnetic radiation within the shielded electronic module 100.

The systems and methods for compartmental integrated shielding of an electronic module, according to aspects disclosed herein, may be provided in or integrated into any processor-based device. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

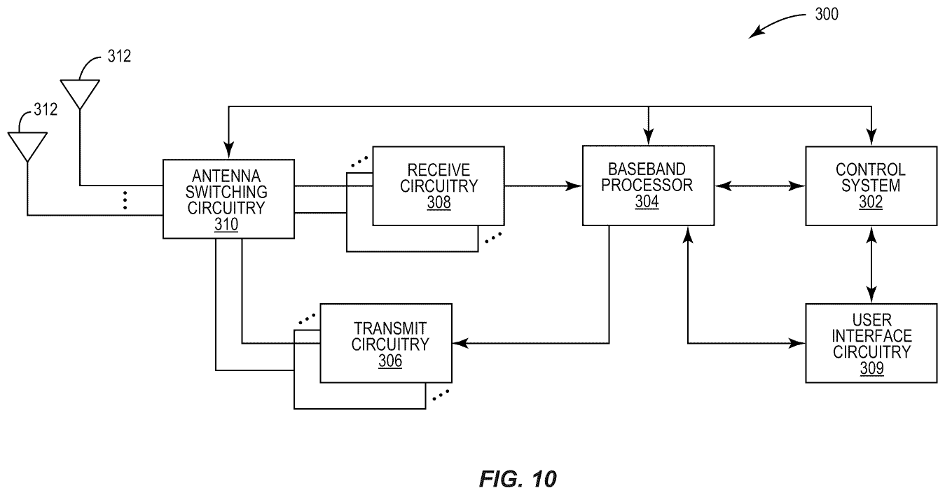

With reference to FIG. 10, the concepts described above may be implemented in various types of communication devices 300, such as those listed in the previous paragraph. The communication device 300 will generally include a control system 302, a baseband processor 304, transmit circuitry 306, receive circuitry 308, and user interface circuitry 309. Optionally, if the communication device 300 is a radio frequency device, the communication devices 300 may further include antenna switching circuitry 310 and multiple antennas 312. Herein, at least one or any combination of the control system 302, the baseband processor 304, the transmit circuitry 306, and the receive circuitry 308 may be implemented in the shielded electronic module 100 (e.g. implemented in the first flip-chip dies 116-1, the second flip-chip dies 116-2, the third flip-chip dies 116-3, and/or the SMDs 116-4) described above.

In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 312 through the antenna switching circuitry 310. The multiple antennas 312 and the replicated transmit and receive circuitries 306, 308 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A shielded electronic module comprising:
an electronic module comprising an interposer, a mold compound, at least one first device component, at least one second device component, and a first interior shield wall, wherein:
the at least one first device component and the at least one second device component are formed over a top surface of the interposer;
the mold compound resides over the top surface of the interposer and fully encapsulates the at least one first device component and the at least one second device component; and
the first interior shield wall is a continuous metal sheet and extends vertically through the mold compound towards the top surface of the interposer to separate the at least one first device component and the at least one second device component, wherein a top surface of the electronic module includes a top surface of the mold compound and a top surface of the first interior shield wall; and
a module shielding structure directly and completely covering the top surface and side surfaces of the electronic module, wherein the module shielding structure and the first interior shield wall are physically and electrically connected.

2. The shielded electronic module of claim 1 wherein the electronic module further includes at least one third device component and a second interior shield wall, wherein:
the at least one third device component is formed over the top surface of the interposer, and the mold compound fully encapsulates the at least one third device component;
the second interior shield wall is a continuous metal sheet and extends vertically through the mold compound towards the top surface of the interposer to separate the at least one first device component from the at least one third device component, wherein the top surface of the electronic module further includes a top surface of the second interior shield wall; and
the module shielding structure and the second interior shield wall are physically and electrically connected.

3. The shielded electronic module of claim 2 wherein the first interior shield wall and the second interior shield wall are separated from each other.

4. The shielded electronic module of claim 2 wherein the first interior shield wall and the second interior shield wall are physically connected to each other.

5. The shielded electronic module of claim 1 wherein the electronic module further includes at least one third device component, wherein:
the at least one third device component is formed over the top surface of the interposer, and the mold compound fully encapsulates the at least one third device component; and
the first interior shield wall separates the at least one third device component from the at least one first device component.

6. The shielded electronic module of claim 5 wherein no interior shield wall is between the at least one second device component and the at least one third device component.

7. The shielded electronic module of claim 1 wherein the first interior shield wall includes a plurality of holes.

8. The shielded electronic module of claim 1 wherein the first interior shield wall is in the shape of a rectangle, a square, a trapezoid, or a combination thereof.

9. The shielded electronic module of claim 1 wherein the first interior shield wall is a copper sheet.

10. The shielded electronic module of claim 1 wherein the first interior shield wall has a width of at least 100 μm, and a thickness of at least 25 μm.

11. The shielded electronic module of claim 1 wherein each of the at least one first device component and the at least one second device component is a flip-chip die, a wire-bonding die, a surface mounted device (SMD), an inductor, a capacitor, or a resistor.

12. The shielded electronic module of claim 1 wherein:
the at least one first device component comprises a plurality of first device components;
the at least one second device component comprises a plurality of second device components; and
the first interior shield wall separates the plurality of first device components from the plurality of second device components.

13. The shielded electronic module of claim 12 wherein the electronic module further includes at least one third device component and a second interior shield wall, wherein:
the at least one third device component is formed over the top surface of the interposer, and the mold compound fully encapsulates the at least one third device component;
the first interior shield wall separates the plurality of first device components from the at least one third device component;
the second interior shield wall is a continuous metal sheet and extends vertically through the mold compound towards the top surface of the interposer to separate the at least one third device component from certain ones of the plurality of second device components, wherein the top surface of the electronic module further includes a top surface of the second interior shield wall; and
the module shielding structure and the second interior shield wall are physically and electrically connected.

14. A method comprising:
providing a first assembly including an interposer, a first device component, a second device component, and a sacrificial shielding structure, wherein:
the first device component and the second device component are formed over a top surface of the interposer;
the sacrificial shielding structure, which at least includes a sacrificial joining member, a first interior shield wall, and a second interior shield wall, is formed over the top surface of the interposer, wherein the sacrificial joining member is configured to keep the first interior shield wall and the second interior shield wall tied together; and
the first device component is covered by the sacrificial shielding structure, while the second device component is outside the sacrificial shielding structure, such that the first device component and the second device component are separated by the first interior shield wall, wherein the first interior shield wall and the second interior shield wall are taller than the first device component and the second device component;
applying a mold compound over the top surface of the interposer to fully encapsulate the first device component, the second device component, and the sacrificial shielding structure;
thinning down the mold compound to provide an electronic module, wherein the mold compound is thinned down until the sacrificial joining member is removed and the first interior shield wall and the second interior shield wall are exposed through the mold compound, such that a top surface of the electronic module includes a top surface of the mold compound and exposed top surfaces of the first interior shield wall and the second interior shield wall; and
applying a mold shielding structure to directly and completely cover the top surface and side surfaces of the electronic module, such that the module shielding structure is physically and electrically connected to the first interior shield wall and the second interior shield wall.

15. The method of claim 14 wherein the sacrificial shielding structure, which is over the top surface of the interposer, is formed by:
providing a metal sheet;
etching portions of the metal sheet to provide an etched metal sheet, wherein:
the etched metal sheet includes at least a joining portion, a first wall portion, and a second wall portion; and
the joining portion is connected to both the first wall portion and the second wall portion; and
bending down each of the first wall portion and the second wall portion to provide the sacrificial shielding structure, wherein:
the first bent-down wall portion forms the first interior shield wall of the sacrificial shielding structure;
the second bent-down wall portion forms the second interior shield wall of the sacrificial shielding structure; and
the unbent joining portion forms the sacrificial joining member of the sacrificial shielding structure.

16. The method of claim 14 wherein the sacrificial shielding structure, which is over the top surface of the interposer, is formed by:
providing a metal sheet, the first interior shield wall, and the second interior shield wall; and
welding the first interior shield wall and the second interior shield wall on a bottom surface of the metal sheet.

17. The method of claim 14 wherein:
the interposer includes connection pads and connection tracks on the top surface of the interposer;
providing the first assembly comprises:
placing the first device component and the second device component over the top surface of the interposer, wherein the first device component and the second device component are connected to corresponding connection pads, respectively;
placing the sacrificial shielding structure over the top surface of the interposer, wherein the first interior shield wall and the second interior shield wall are connected to corresponding connection tracks, respectively; and
soldering the first device component, the second device component, the first interior shield wall, and the second interior shield wall to the interposer simultaneously.

18. The method of claim 14 wherein each of the first interior shield wall and the second interior shield wall is a copper sheet.

19. The method of claim 18 wherein each of the first interior shield wall and the second interior shield wall includes a plurality of holes.

20. The method of claim 18 wherein each of the first interior shield wall and the second interior shield wall has a width of at least 100 μm, and a thickness of at least 25 μm.

21. The method of claim 14 wherein each of the first device component and the second device component is a flip-chip die, a wire-bonding die, a surface mounted device (SMD), an inductor, a capacitor, or a resistor.

22. A communication device comprising:
a control system;
a baseband processor;
receive circuitry; and
transmit circuitry, wherein at least one or any combination of the control system, the baseband processer, the transmit circuitry, and the receive circuitry is implemented in a shielded electronic module, which includes an electronic module with an interposer, a mold compound, at least one first device component, at least one second device component, and a first interior shield wall, and a module shielding structure directly and completely covering a top surface and side surfaces of the electronic module, wherein:
the at least one first device component and the at least one second device component are formed over a top surface of the interposer;
the mold compound resides over the top surface of the interposer and fully encapsulates the at least one first device component and the at least one second device component;
the first interior shield wall is a continuous metal sheet and extends vertically through the mold compound towards the top surface of the interposer to separate the at least one first device component and the at least one second device component, wherein the top surface of the electronic module includes a top surface of the mold compound and a top surface of the first interior shield wall; and
the module shielding structure is physically and electrically connected to the first interior shield wall.
